(19) United States
(12) Patent Application Publication
(10) Pub. No.: US 2023/0079207 A1
(43) Pub. Date: Mar. 16, 2023

(54) SEMICONDUCTOR MANUFACTURING APPARATUS

(71) Applicant: Kioxia Corporation, Tokyo (JP)

(72) Inventor: Makoto BABA, Yokkaichi (JP)

(21) Appl. No.: 17/687,412

(22) Filed: Mar. 4, 2022

(30) Foreign Application Priority Data
Sep. 13, 2021 (JP) 2021-148551

(51) Int. Cl. H01L 21/683; H01J 37/32; C23C 16/458; C23C 16/46; C23C 16/50; C23C 16/455

(52) U.S. Cl. CPC H01L 21/6833; H01J 37/32724; H01J 37/32568; C23C 16/4586; C23C 16/46; C23C 16/50; C23C 16/45536; H01J 2237/332; H01J 2237/2007

(57) ABSTRACT

A semiconductor manufacturing apparatus includes an electrostatic chuck that attracts a workpiece including a substrate. The electrostatic chuck includes an attraction surface that includes a first region and a second region surrounding the first region; and an internal electrode superimposed on each of the first region and the second region in a first direction crossing the attraction surface. The first region has a first depth in the first direction with respect to the attraction surface and includes a first recessed portion superimposed on the internal electrode in the first direction. The second region has a second depth smaller than the first depth in the first direction with respect to the attraction surface and includes a second recessed portion superimposed on the internal electrode in the first direction.

### CROSS-REFERENCE TO RELATED APPLICATION(S)

This application is based upon and claims the benefit of priority from No. 2021-148551, filed Sep. 13, 2021, the entire contents of which are incorporated herein by reference.

### FIELD

Embodiments described herein relate generally to a semiconductor manufacturing apparatus.

### BACKGROUND

A semiconductor manufacturing apparatus including an electrostatic chuck that attracts a workpiece including a substrate of a semiconductor wafer or the like has recently been known.

### DESCRIPTION OF THE DRAWINGS

FIG. 1 is a schematic cross-sectional view illustrating a configuration example of a semiconductor manufacturing apparatus.

FIG. 2 is a schematic top view illustrating an example of a structure of an attraction surface 21.

FIG. 3 is a schematic top view illustrating a first example of a structure of a region 21b.

FIG. 4 is a schematic top view illustrating the first example of the structure of the region 21b.

FIG. 5 is a schematic top view illustrating a second example of the structure of the region 21b.

FIG. 6 is a schematic cross-sectional view illustrating the second example of the structure of the region 21b.

FIG. 7 is a schematic cross-sectional view illustrating an attraction mechanism.

### DETAILED DESCRIPTION

At least one embodiment provides a semiconductor manufacturing apparatus including an electrostatic chuck that has a high attraction force.

In general, according to at least one embodiment, a semiconductor manufacturing apparatus includes an electrostatic chuck that attracts a workpiece including a substrate. The electrostatic chuck includes an attraction surface that includes a first region and a second region surrounding the first region; and an internal electrode superimposed on each of the first region and the second region in a first direction crossing the attraction surface. The first region has a first depth in the first direction with respect to the attraction surface and includes a first recessed portion superimposed on the internal electrode in the first direction. The second region has a second depth smaller than the first depth in the first direction with respect to the attraction surface and includes a second recessed portion superimposed on the internal electrode in the first direction.

Embodiments will be described hereinafter with reference to the drawings. Relationships between thicknesses and plane dimensions of elements, proportions of the thicknesses of the elements illustrated in the drawings may differ from actual relationships and the like. In addition, in the embodiments, substantially the same elements are denoted by the same reference signs and descriptions thereof are omitted as appropriate.

(Configuration Example of Semiconductor Manufacturing Apparatus)

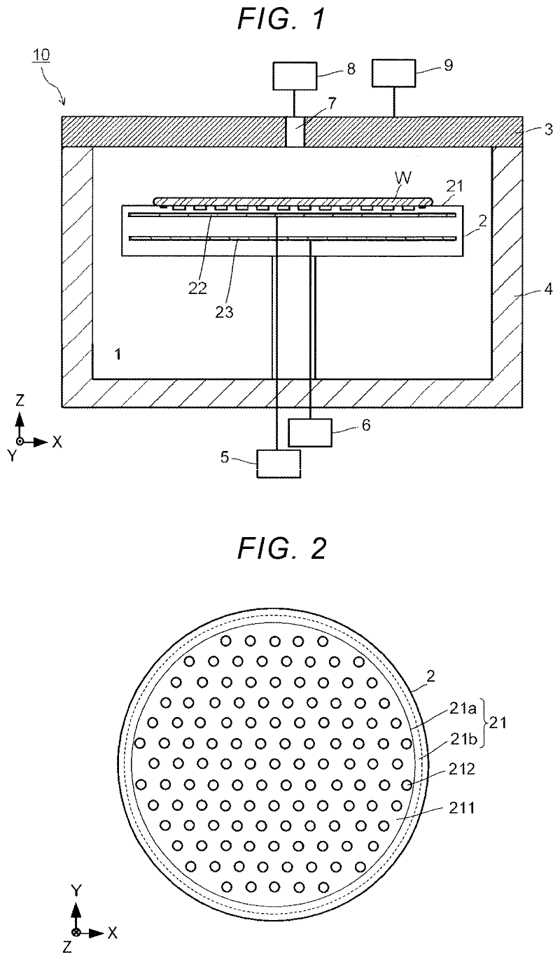

FIG. 1 is a schematic cross-sectional view illustrating a configuration example of a semiconductor manufacturing apparatus. A semiconductor manufacturing apparatus 10 includes a chamber 1, a stage 2, an upper electrode 3, and an outer wall 4. Examples of the semiconductor manufacturing apparatus 10 include a plasma CVD apparatus and a plasma ALD apparatus.

The chamber 1 is a space surrounded by the upper electrode 3 and the outer wall 4. In the chamber 1, a process such as a film formation process is performed on a workpiece W. Examples of the workpiece W include a substrate of a semiconductor wafer or the like. The outer wall 4 has an inlet/outlet port used to load and unload the workpiece W.

The stage 2 forms an electrostatic chuck that attracts the workpiece W. The stage 2 has an attraction surface 21, an internal electrode 22, and a heater 23.

The attraction surface 21 is a surface for attracting the workpiece W. A contact portion of the attraction surface 21 in contact with the workpiece W is formed from, for example, a ceramic material.

The internal electrode 22 is superimposed on the attraction surface 21 in a Z-axis direction crossing a surface of the workpiece W. The internal electrode 22 is embedded in the stage 2. The internal electrode 22 is connected to a direct-current power supply 5. The direct-current power supply 5 supplies, for example, a direct-current voltage used to attract the workpiece W. The direct-current power supply 5 may have a switch and switch over between a start and a stop of supply of the direct-current voltage using the switch. The internal electrode 22 may have a function as an electrode used when plasma is generated in the chamber 1.

The heater 23 has a function to heat the stage 2 and to regulate a temperature of the stage 2. The heater 23 is connected to a heater power supply 6.

The upper electrode 3 is superimposed on the internal electrode 22 in the Z-axis direction. The upper electrode 3 may have a gas inlet 7 and supply a source gas from a gas supply source 8 via the gas inlet 7. The gas supply source 8 may have, for example, a mass flow controller connected to a source tank and regulate a gas flow rate using the mass flow controller. A plurality of mass flow controllers may be provided per source gas.

The upper electrode 3 is connected to an alternating-current power supply 9. The alternating-current power supply 9 can apply high-frequency power for generating plasma from the source gas to the upper electrode 3. While a frequency of the high-frequency power is not limited to a specific one, the frequency is, for example, equal to or higher than 200 kHz and equal to or lower than 13.56 MHz. The alternating-current power supply 9 may have a matching box and supply the high-frequency power to the upper electrode 3 via the matching box.

The stage 2, the direct-current power supply 5, the heater power supply 6, the gas supply source 8, and the alternating-current power supply 9 may be controlled by, for example, a control circuit, not illustrated. The control circuit may be configured with hardware using, for example, a processor. It is noted that each operation may be stored, as an operation program, in a computer-readable storage medium such as a memory and each operation may be executed by causing hardware to read the operation program stored in the storage medium as appropriate.

The semiconductor manufacturing apparatus 10 may include a carrying mechanism, not illustrated. The carrying mechanism can load and unload the workpiece W to and from the chamber 1. This enables the workpiece W to be placed on the stage 2. The carrying mechanism may be controlled by, for example, the control circuit described above.

FIG. 2 is a schematic top view illustrating an example of a structure of the attraction surface 21. FIG. 2 illustrates an X-Y plane in parallel to the attraction surface 21. The attraction surface 21 includes regions 21a and 21b. Each of the regions 21a and 21b is superimposed on the internal electrode 22 in the Z-axis direction crossing the attraction surface 21.

The region 21a is provided inward of a periphery of the attraction surface 21. The region 21a has a recessed portion 211 and a contact portion 212.

The recessed portion 211 is provided, for example, circularly along an outer periphery of the attraction surface 21. The recessed portion 211 has a depth in the Z-axis direction with respect to the attraction surface 21.

The contact portion 212 is a portion that comes in contact with the workpiece W when the workpiece W is attracted. A planar shape of the contact portion 212 is, for example, a circular shape. Providing the contact portion 212 makes it possible to enhance a holding force for holding the workpiece W when the workpiece W is placed on the attraction surface 21. While a diameter of the contact portion 212 is not limited to a specific one in the X-Y plane, the diameter is, for example, equal to or greater than one mm and equal to or smaller than ten mm. FIG. 2 illustrates a plurality of contact portions 212 provided in a dot-like fashion in the X-Y plane. The number of the plurality of contact portions 212 is not limited to the number of contact portions 212 illustrated in FIG. 2. The planar shape of the plurality of contact portions 212 is not limited to the circular shape.

The region 21b surrounds the region 21a in the X-Y plane. The region 21b is provided inward of the periphery of the attraction surface 21. That is, the region 21b is disposed between the periphery of the attraction surface 21 and the region 21a in the X-Y plane. When the electrostatic chuck attracts the workpiece W, a periphery of the substrate provided in the workpiece W is superimposed on the region 21b in the Z-axis direction.

### First Example of Structure of Region 21b

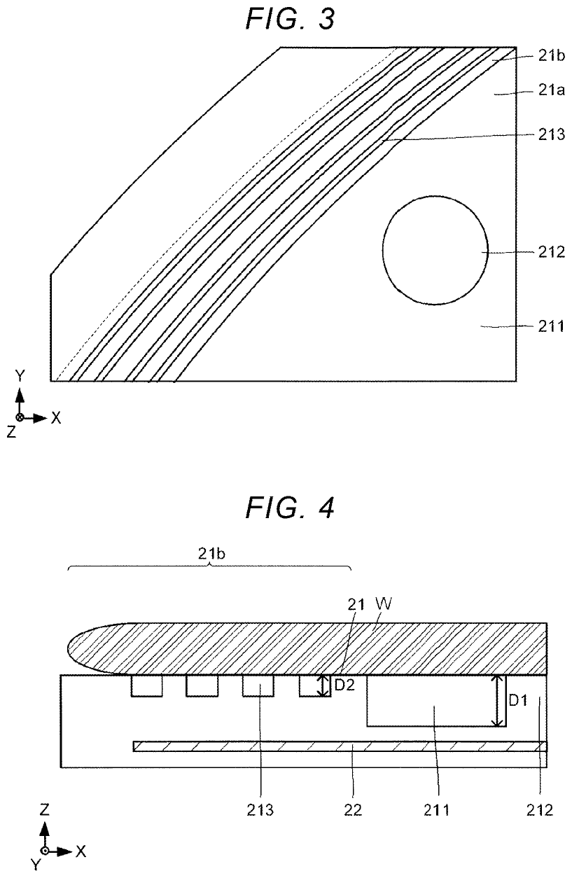

FIG. 3 is a schematic top view illustrating a first example of a structure of the region 21b. FIG. 4 is a schematic cross-sectional view illustrating the first example of the structure of the region 21b. The region 21b illustrated in FIGS. 3 and 4 corresponds to part of the region 21b illustrated in FIG. 2.

The region 21b has a recessed portion 213. The recessed portion 213 has, for example, an annular shape surrounding the region 21a in the X-Y plane. FIG. 3 illustrates part of a plurality of annular recessed portions 213 provided concentrically. The number of the plurality of recessed portions 213 is not limited to the number of recessed portions 213 illustrated in FIGS. 3 and 4.

The recessed portions 213 are superimposed on the internal electrode 22 in the Z-axis direction crossing the attraction surface 21. When the recessed portion 211 has a depth D1 in the Z-axis direction with respect to the attraction surface 21, each recessed portion 213 has a depth D2 smaller than the depth D1 in the Z-axis direction with respect to the attraction surface 21. A cross-sectional shape of each recessed portion 213 is not limited to a specific shape.

### Second Example of Structure of Region 21b

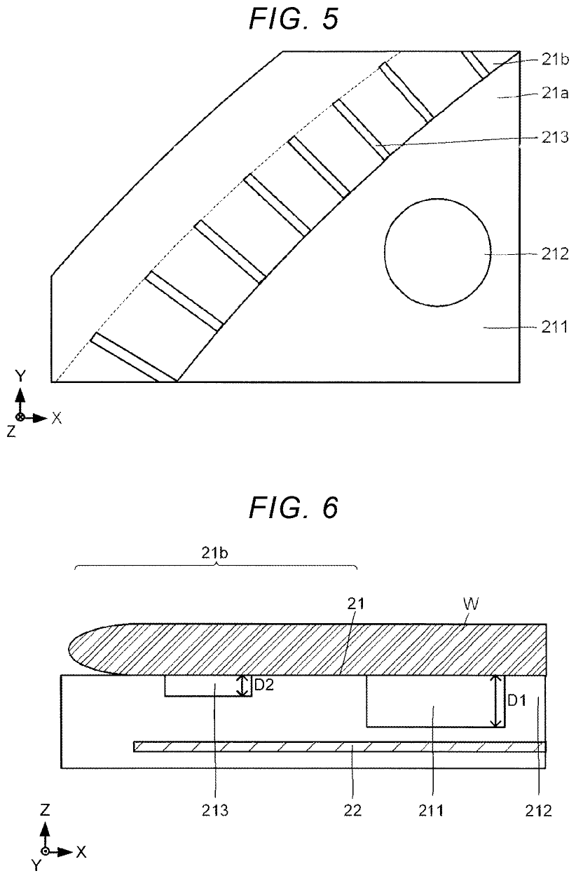

FIG. 5 is a schematic top view illustrating a second example of the structure of the region 21b. FIG. 6 is a schematic top view illustrating the second example of the structure of the region 21b. The region 21b illustrated in FIGS. 5 and 6 corresponds to part of the region 21b illustrated in FIG. 2.

The region 21b has the recessed portion 213. The recessed portion 213 extends, for example, from an inner periphery to an outer periphery of the region 21a in the X-Y plane. FIG. 5 illustrates part of the plurality of recessed portions 213 provided radially. The number of the plurality of recessed portions 213 is not limited to the number of recessed portions 213 illustrated in FIGS. 5 and 6.

The recessed portions 213 are superimposed on the internal electrode 22 in the Z-axis direction. When the recessed portion 211 has the depth D1 in the Z-axis direction with respect to the attraction surface 21, each recessed portion 213 has the depth D2 smaller than the depth D1. The cross-sectional shape of each recessed portion 213 is not limited to a specific shape.

While the depth D1 is not limited to a specific one in the first and second examples of the structure, the depth D1 is, for example, equal to or greater than 20 μm and equal to or smaller than 30 μm, preferably equal to or greater than 22 μm and equal to or smaller than 26 μm. While the depth D2 is not limited to a specific one, the depth D2 is, for example, equal to or greater than 5 μm and equal to or smaller than 15 μm, preferably equal to or greater than 8 μm and equal to or smaller than 13 μm.

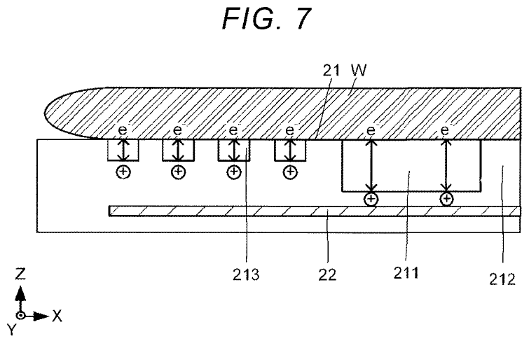

FIG. 7 is a schematic cross-sectional view illustrating an attraction mechanism when the workpiece W is attracted. FIG. 7 illustrates an example of a case where the region 21b has the first example of the structure.

When a direct-current voltage is applied to the internal electrode 22, an attraction force is generated by attraction of positive charges and negative charges between the stage 2 and the workpiece W. This attraction force results from, for example, a Johnsen-Rahbek force (J-R force) generated between the stage 2 and the workpiece W or a Coulomb's force generated between the attraction surface 21 and the workpiece W. While FIG. 7 illustrates the positive charges closer to the stage 2 and the negative charges closer to the workpiece W, a way of attraction is not limited to this example.

When an existing electrostatic chuck performs a film formation process at a high temperature equal to or higher than, for example, 650° C., a stage becomes a conductor due to a reduction in electrical resistance and it may be difficult to retain charges necessary for the chuck. This causes a reduction in chuck force. Since a semiconductor substrate provided in a workpiece greatly warps in a peripheral portion, it is preferable that the attraction force is high in a superimposed portion (also referred to as “Ledge”) where the attraction surface is superimposed on the periphery of the substrate.

It is considered to provide a plurality of internal electrodes and apply different voltages to Ledges to enhance the attraction force in the Ledges. However, this makes the structure of the stage complicated and it is difficult to manufacture the stage.

In the semiconductor manufacturing apparatus 10, the recessed portions 213 shallower than the recessed portion 211 are formed in the region 21b that corresponds to the Ledge. The Coulomb's force or the J-R force becomes higher as a distance between the stage 2 and the workpiece W is shorter. Therefore, forming the recessed portions 213 shallower than the recessed portion 211 makes it possible to enhance the attraction force in the Ledge.

The recessed portions 211 and 213 can be formed by, for example, partially machining the surface of the attraction surface 21 using a method such as etching. When the recessed portions 211 and 213 are formed by machining the surface of the attraction surface 21, larger variations in depths occur in proportion to deeper recessed portions. In the semiconductor manufacturing apparatus 10 according to the embodiment, by contrast, forming the recessed portions 213 shallower than the recessed portion 211 makes it possible to reduce the variations in depths of the recessed portions.

Furthermore, in the semiconductor manufacturing apparatus 10 according to the embodiment, it is possible to reduce a contact area between the attraction surface 21 and the workpiece W in the region 21b by forming the recessed portions 213. When the contact area between the attraction surface 21 and the workpiece W is large in the region 21b, then a contact surface of the workpiece W in contact with the attraction surface 21 is prone to be damaged, often resulting in, for example, a high surface roughness of the substrate provided in the workpiece W. Reducing the contact area between the attraction surface 21 and the workpiece W, by contrast, makes it possible to reduce, for example, the surface roughness of the substrate.

The planar shape of the recessed portions 213 is not limited to the shapes illustrated in the first and second examples of the structure of the region 21b. In a case of forming the plurality of recessed portions 213, the number of recessed portions 213 in one location of the region 21b may differ from the number of recessed portions 213 in another location thereof. For example, when a magnitude of warpage of the substrate in an X-axis direction differs from a magnitude of warpage in a Y-axis direction, the number of recessed portions 213 may be increased in a larger warpage location and the number of recessed portions 213 may be decreased in a smaller warpage location.

Moreover, in the first and second examples of the structure of the region 21b, the example of superimposing the recessed portions 213 on the internal electrode 22 in the Z-axis direction is described. However, when the attraction of charges can be generated via the recessed portions 213, the recessed portions 213 may not necessarily be superimposed on the internal electrode 22.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor manufacturing apparatus comprising:
an electrostatic chuck configured to attract a workpiece, the electrostatic chuck including:
an attraction surface including a first region and a second region, the second region surrounding the first region; and
an internal electrode superimposed on each of the first region and the second region in a first direction, the first direction crossing the attraction surface,
the first region has a first depth in the first direction, the first region including a first recessed portion superimposed on the internal electrode in the first direction, and
the second region has a second depth smaller than the first depth in the first direction, the second region including a second recessed portion superimposed on the internal electrode in the first direction.

2. The semiconductor manufacturing apparatus according to claim 1, wherein
the second recessed portion is an annular recessed portion surrounding the first region.

3. The semiconductor manufacturing apparatus according to claim 1, wherein
the second recessed portion extends from an inner periphery to an outer periphery of the second region.

4. The semiconductor manufacturing apparatus according to claim 1, further comprising
a heater configured to heat the electrostatic chuck.

5. The semiconductor manufacturing apparatus according to claim 1, wherein
the workpiece includes a substrate, and the electrostatic chuck is configured such that when it attracts the workpiece, a periphery of the substrate is superimposed on the second region in the first direction.

6. The semiconductor manufacturing apparatus according to claim 1, wherein the attraction surface is formed of a ceramic material.

7. The semiconductor manufacturing apparatus according to claim 1, wherein the electrostatic chuck includes a contact portion arranged to contact the substrate when the substrate is attracted to the attraction surface.

8. The semiconductor manufacturing apparatus according to claim 7, wherein the contact portion has a circular shape.

9. The semiconductor manufacturing apparatus according to claim 7, wherein the contact portion includes a plurality of contact portions.

10. The semiconductor manufacturing apparatus according to claim 9, wherein the plurality of contact portions are arranged in an array.

11. The semiconductor manufacturing apparatus according to claim 1, wherein
the first recessed portion includes a plurality of first recessed portions, and
the second recessed portion includes a plurality of second recessed portions that is greater than a number of the plurality of first recessed portions.

12. The semiconductor manufacturing apparatus according to claim 1, wherein the second recessed portion includes a plurality of second recessed portions arranged concentrically.

13. The semiconductor manufacturing apparatus according to claim 1, wherein the second recessed portion includes a plurality of second recessed portions arranged radially relative to the attraction surface.

14. The semiconductor manufacturing apparatus according to claim 1, wherein the second recessed portion includes a plurality of second recessed portions.

15. The semiconductor manufacturing apparatus according to claim 14, wherein
the workpiece includes a substrate, and
the density of the second recessed portions is larger in a region of the substrate having greater warpage.
